(19) United States
(12) Patent Application Publication
(10) Pub. No.: US 2015/0156909 A1
(43) Pub. Date: Jun. 4, 2015

(54) POWER SEMICONDUCTOR MODULE

(71) Applicant: SAMSUNG ELECTRO-MECHANICS CO., LTD., Suwon-Si (KR)

(72) Inventors: Young Hoon Kwak, Suwon-Si (KR); Chang Seob Hong, Suwon-Si (KR); Young Ki Lee, Suwon-Si (KR)

(73) Assignee: SAMSUNG ELECTRO-MECHANICS CO., LTD., Suwon-Si (KR)

(21) Appl. No.: 14/270,167

(22) Filed: May 5, 2014

(30) Foreign Application Priority Data
Nov. 29, 2013 (KR) 10-2013-0147544

(51) Int. Cl. H05K 7/14

(52) U.S. Cl. CPC H05K 7/14

(57) ABSTRACT

Disclosed herein is a power semiconductor module including a module housing comprising an accommodation space formed therein and fixing portions formed on an external surface thereof, a printed circuit board included in the module housing, exposed through the accommodation space, and comprising circuit patterns (Cu patterns) on which power devices are arranged, and a terminal fixedly coupled to the fixing portion, and comprising an input end for receiving power and leads adhered to a circuit pattern between the power devices and for distribution of supplied current. Accordingly, stray inductance may be effectively reduced, and thus, current distribution between power devices may be balanced, thereby effectively preventing a surge voltage from increasing.

### CROSS REFERENCE TO RELATED APPLICATION

This application claims the benefit of Korean Patent Application No. 10-2013-0147544, filed on Nov. 29, 2013, entitled “Power Semiconductor Module”, which is hereby incorporated by reference in its entirety into this application.

### BACKGROUND OF THE INVENTION

1. Technical Field

The present invention relates to a power semiconductor module.

2. Description of the Related Art

A power semiconductor module is disclosed in Patent Document 1 below in detail. According to Patent Document 1, the power semiconductor module includes a housing with a housing frame, and a carrier pluggable in the housing frame. In addition, the carrier is configured with a lead that includes an internal portion arranged inside the housing and an external portion arranged outside the housing. Here, the internal portion of the carrier is electrically coupled to an electronic device of the power semiconductor module, and the external portion of the carrier allows for electrically coupling the power semiconductor module. In addition, the carrier pluggable in the housing frame is plugged in the housing frame.

### PRIOR ART DOCUMENT

(Patent Document 1) US 2010-0014269 A1

### SUMMARY OF THE INVENTION

The present invention has been made in an effort to provide an improved power semiconductor module compared with a conventional power semiconductor module such as in Patent Document 1 above.

The present invention has been made in an effort to provide a power semiconductor module for easily balancing power distribution between devices and easily adhering a terminal to the power semiconductor module.

According to an embodiment of the present invention, there is provided a power semiconductor module, including: a module housing including an accommodation space formed therein and fixing portions formed on an external surface thereof, a printed circuit board included in the module housing, exposed through the accommodation space, and including circuit patterns (Cu patterns) on which power devices are arranged, and a terminal fixedly coupled to the fixing portion, and including an input end for receiving power and leads adhered to a circuit pattern between the power devices and for distribution of supplied current.

The fixing portion may be formed with a groove with a concave shape so as to accommodate opposite ends of the terminal.

The terminal may be fixedly bolt-coupled to the fixing portion of the module housing.

The terminal may include a body portion including an input end, a coupling portion protruding from the body portion and fixedly coupled to the fixing portion of the module housing, and an adhesive portion protruding from the body portion and including a lead at an end thereof.

The power semiconductor module may further include springs interposed between opposite ends of the terminal and the fixing portion of the module housing.

According to another embodiment of the present invention, there is provided a power semiconductor module including: a module housing including an accommodation space formed therein and fixing portions formed on an external surface thereof, a printed circuit board included in the module housing, exposed through the accommodation space, and including a first circuit pattern on which power devices are arranged, a second circuit pattern that is electrically connected to the first circuit pattern and on which power devices are arranged, and a third circuit pattern that is electrically connected to the second circuit pattern, a first terminal (P-terminal) with opposite ends fixedly coupled to the fixing portion, including an input end for receiving power and leads adhered between power devices of the first circuit pattern and for distributing supplied current, a second terminal (Out-Terminal) with one end fixedly coupled to the fixing portion, including an output end for outputting current and leads adhered between power devices of the second circuit pattern and for distributing current, and a third terminal (N-Terminal) with opposite ends fixedly coupled to the fixing portion, including leads coupled to the third circuit pattern.

The fixing portion may be formed with a groove with a concave shape.

The first, second, and third terminals may be fixedly bolt-coupled to the fixing portion of the module housing.

The first terminal may include a first body portion including an input end, a first coupling portion protruding from opposite ends of the first body portion and fixedly coupled to the fixing portion of the module housing, and a first adhesive portion protruding from the first body portion and including a lead as an end thereof.

The second terminal may include a second body portion including an output end, a second coupling portion protruding from one end of the second body portion and fixedly coupled to the fixing portion of the module housing, and a second adhesive portion protruding from the second body portion and including a lead as an end thereof.

The third terminal may include a third body portion, a third coupling portion protruding from opposite ends of the third body portion and fixedly coupled to the fixing portion of the module housing, and a third coupling portion protruding from the third body portion and including leads as an end thereof.

The power semiconductor module may further include a spring interposed between the first, second, and third terminals and the fixing portion of the module housing.

### BRIEF DESCRIPTION OF THE DRAWINGS

The above and other objects, features and advantages of the present invention will be more clearly understood from the following detailed description taken in conjunction with the accompanying drawings, in which:

FIGS. 1 and 2 are cross-sectional views illustrating a power semiconductor module according to a first embodiment of the present invention;

FIG. 3 is an exploded perspective view illustrating a power semiconductor module according to a second embodiment of the present invention; and

FIGS. 4 and 5 are plan views illustrating the power semiconductor module according to the second embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

A power semiconductor module according to an embodiment of the present invention includes a module housing including an accommodation space formed therein and fixing portions formed on an external surface thereof, a printed circuit board that is included in the module housing, is exposed outward through the accommodation space, and includes circuit patterns (Cu patterns) on which power devices are arranged, and a terminal fixedly coupled to the fixing portions, and including an input end for receiving power and leads adhered to the circuit patterns (Cu patterns) between the power devices and for distributing current.

In general, a power semiconductor module, in detail, for development of a high power metal oxide semiconductor field effect transistor (MOSFET) semiconductor module, it is very important to distribute current between power devices connected in parallel. This is because problems arise in that stray inductance varies according to a terminal for supplying power to the power device and current distribution between the power devices is not balanced to increase a surge voltage.

Here, as well known, in general, a terminal of a power semiconductor module is connected to a module housing by ultrasonic welding or wire bonding after insert injection.

An improved power semiconductor module according to an embodiment of the present invention may uniformly distribute supplied current to power devices through a terminal, thereby effectively reducing the aforementioned stray inductance, and soldering, ultrasonic welding, press contact, etc. may be easily applied while the terminal is adhered to a circuit pattern (Cu pattern) of the substrate during a process.

A power semiconductor module according to an embodiment of the present invention includes a module housing including an accommodation space formed therein and fixing portions formed on an external surface thereof, and a printed circuit board that is included in the module housing and is exposed outward through the accommodation space, and includes a first circuit pattern on which a power device is arranged, a second circuit pattern that is electrically connected to the first circuit pattern and on which a power device is arranged, and a third circuit pattern that is electrically connected to the second circuit pattern.

In addition, the power semiconductor module includes a first terminal (P-Terminal) with opposite ends fixedly coupled to the fixing portion of the module housing, and including an input end for receiving power and a lead adhered between power devices of the first circuit pattern and distributing supplied current, a second terminal (Out-Terminal) with one end fixedly coupled to the fixing portion, including an output end for outputting current to the other end and a lead adhered between power devices of the second circuit pattern, and a third terminal (N-Terminal) with opposite ends fixedly coupled to the fixing portion, including a lead adhered to the third circuit pattern.

Accordingly, the power semiconductor module according to an embodiment of the present invention may uniformly distribute supplied current to power devices through first and second terminals and may output the current through the second terminal, thereby effectively reducing stray inductance, and accordingly, current distribution between power devices may be balanced, thereby effectively preventing a surge voltage from increasing.

Hereinafter, exemplary embodiments of the present invention will be described in detail with reference to the attached drawings.

### First Embodiment

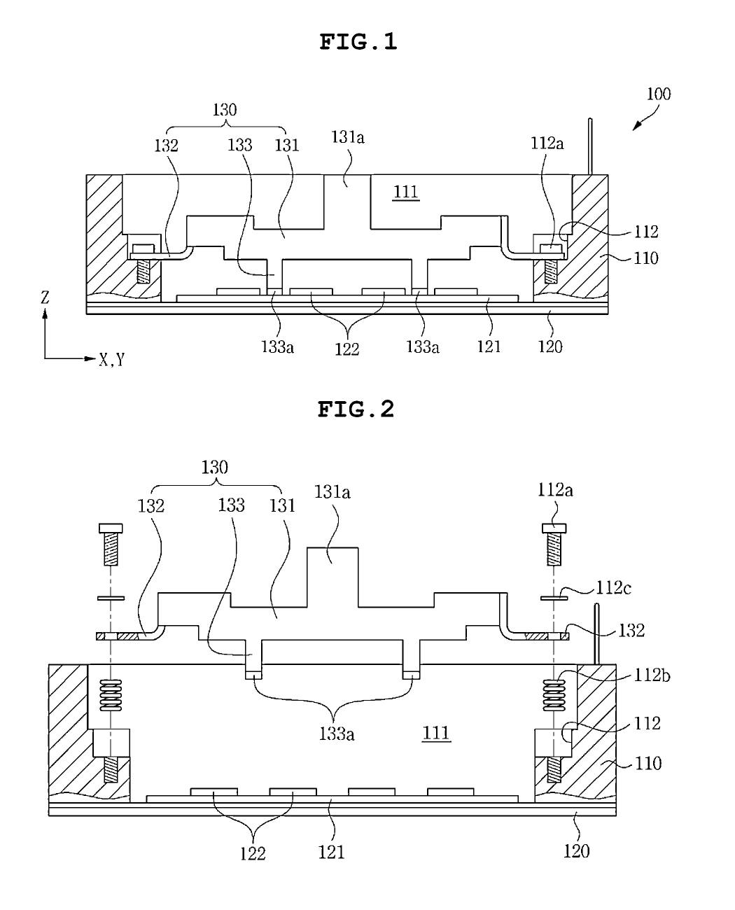

As illustrated in FIG. 1, a power semiconductor module 100 according to the first embodiment of the present invention is configured in such a way that a terminal 130 is fixedly coupled to a module housing 110 using, for example, bolts 112a, and leads 133a of the terminal 130 are coupled to a circuit pattern 121 formed on a substrate 120 via soldering, ultrasonic welding, press contact, etc.

The module housing 110 includes an accommodation space 111 formed therein and fixing portions 112 with an external surface to which the terminal 130 is fixedly coupled. In this case, the fixing portions 112 are formed like a groove with a concave shape and are adjacent to the accommodation space 111. Accordingly, the substrate 120 is disposed below the module housing 110 such that the circuit pattern 121, on which a plurality of power devices 122, i.e., four power devices 122 of FIG. 1 formed on the substrate 120 are arranged, is exposed outward through the accommodation space 111.

The terminal 130 is a component for supplying current to the power devices 122. The terminal includes an input end 131a to which current is supplied and the leads 133a for supplying the supplied current such that opposite ends of the terminal 130 are fixedly coupled to the fixing portions 112 of the module housing 110. In detail, the terminal 130 is configured in such a way that coupling portions 132 with holes, into which the bolts 112a are inserted, protrude from opposite ends of the body portion 131, and are inserted into and are fixedly adhered to the fixing portions 112 with regard to a body portion 131 having the input end 131a, and a pair of adhesive portions 133 protrude from a lower portion of the body portion 131 and the leads 133a as ends of the adhesive portions 133 are adhered to the circuit pattern 121.

Here, the body portion 131 is arranged in a Z-axis direction perpendicular to a direction (X-axis direction) in which the substrate 120 is disposed. In addition, the coupling portions 132 are bent from the body portion 131 so as to be arranged in the X-axis direction like the substrate 120, and the leads 133a formed at ends of the adhesive portions 133 are also bent at the adhesive portions 133 so as to be arranged in the Y-axis direction. The terminal 130 including the body portion 131, the coupling portions 132, and the adhesive portions 133 may be prepared in a press type.

Accordingly, with regard to the power semiconductor module 100 according to the first embodiment of the present invention, the leads 133a may be easily coupled onto the circuit pattern 121 of the substrate 120 while the terminal 130 is fixed to the module housing 110. In this case, as a coupling method, soldering, ultrasonic welding, etc. may be easily applied.

In addition, the leads 133a may be arranged between the power devices 122 so as to uniformly distribute power to the right and left power devices 122, thereby effectively reducing stray inductance, and accordingly, current distribution may be balanced, thereby effectively preventing surge voltage from increasing.

As illustrated in FIG. 2, a spring 112b is inserted and interposed between the terminal 130 and the fixing portion 112 of the module housing 110. In addition, a washer 112c is interposed between the terminal 130 and each of the bolts 112a.

Accordingly, press contact may be easily applied as a coupling method between the terminal 130 and the substrate 120. That is, the spring 112b may support the terminal 130 via elastic force to effectively prevent the substrate 120 from being damaged, which occurs during press contact.

### Second Embodiment

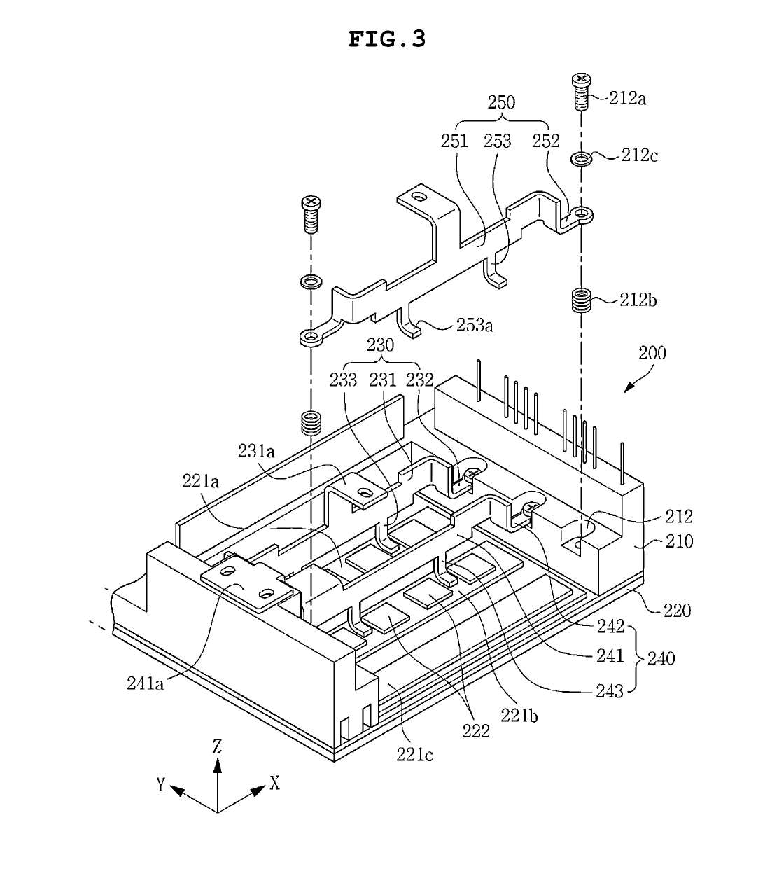

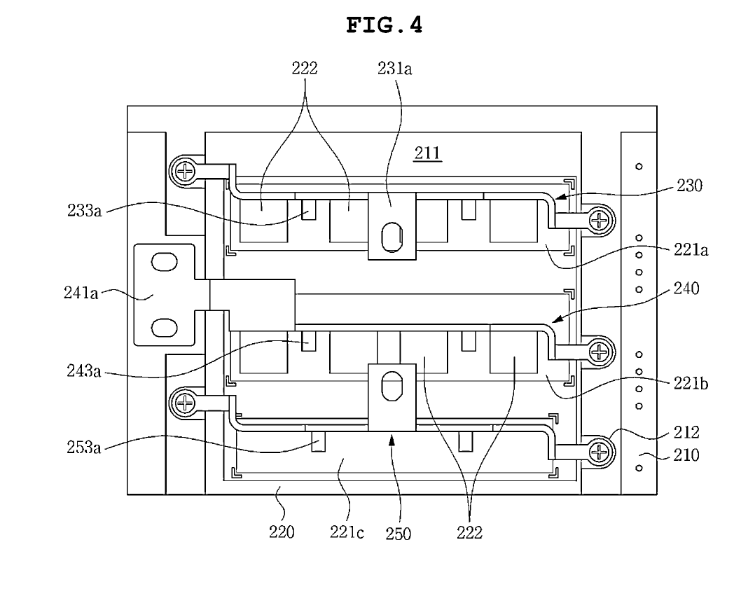

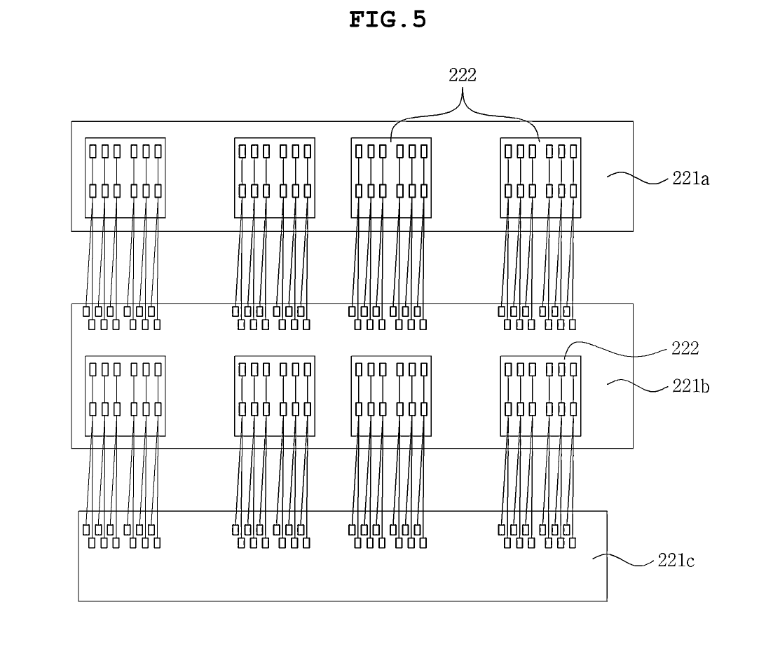

As illustrated in FIGS. 3 to 5, a power semiconductor module 200 according to a second embodiment of the present invention is configured in such a way that first, second, and third terminals 230, 240, and 250 are fixedly coupled to a module housing 210 using, for example, bolts 212a, and leads 233a, 243a, and 253a respectively formed on the first, second, and third terminals 230, 240, and 250 are coupled to first, second, and third circuit patterns 221a, 221b, and 221c formed on a substrate 220 via soldering, ultrasonic welding, press contact, etc.

The module housing 210 includes an accommodation space 211 formed therein and fixing portions 212 with an external surface to which the first, second, and third terminals 230, 240, and 250 are fixedly coupled. In this case, the fixing portions 212 are formed like a groove with a concave shape and are adjacent to the accommodation space 211.

Accordingly, the substrate 220 is disposed below the module housing 210 such that the first, second, and third circuit patterns 221a, 221b, and 221c formed on the substrate 220 are exposed outward through the accommodation space 211. Here, a plurality of power devices 222, i.e., four power devices 222 of FIGs are arranged on the first and second circuit patterns 221a and 221b. The third circuit pattern 221c may be preparatorily used, and the power devices 222 and the second and third circuit patterns 221b and 221c are electrically connected via wire.

The first terminal 230 is a component for supplying current to the power devices 222. The first terminal 230 includes an input end 231a to which current is supplied and the lead 233a for supplying the supplied current such that opposite ends of the first terminal 230 are fixedly coupled to the fixing portions 212 of the module housing 210. In detail, the first terminal 230 is configured in such a way that a first coupling portion 232 with a hole, into which the bolts 212a are inserted, protrude from opposite ends of the first body portion 231, and are inserted into and are fixedly adhered to the fixing portions 212 with regard to a first body portion 231 having the input end 231a, and a pair of first adhesive portions 233 protrude from a lower portion of the first body portion 231 and the lead 233a as ends of the first adhesive portions 233 are adhered to the first circuit pattern 221a.

The second terminal 240 is a component for outputting supplied current. In detail, the second terminal 240 is configured in such a way that a second coupling portion 242 protrudes from one end of the second body portion 241, and is inserted into and is fixedly adhered to the fixing portions 212 with regard to a second body portion 241 having an output end 241a for outputting current, and a pair of second adhesive portions 243 protrude from a lower portion of the second body portion 241 and the lead 243a as an end of the second adhesive portions 243 is adhered to the second circuit pattern 221b to distribute current.

The third terminal 250 is configured in such a way that a third coupling portion 252 protrudes from opposite ends of the third body portion 251, and is inserted into and is fixedly adhered to the fixing portions 212 with regard to a third body portion 251, and a pair of third adhesive portions 253 protrudes from a lower portion of the third body portion 251 and the lead 253a as an end of the third adhesive portion 253 is adhered to the third circuit pattern 221c to supply current.

Here, the first, second, and third terminals 230, 240, and 250 have the common feature in that the first, second, and third body portions 231, 241, and 251 are arranged in a Z-axis direction perpendicular to a direction (X-axis direction) in which the substrate 220 is disposed. In addition, the first, second, and third coupling portions 232, 242, and 252 are bent from the first, second, and third body portions 231, 241, and 251 so as to be arranged in the X-axis direction like the substrate 220, and the leads 233a, 243a, and 253a formed at ends of the first, second, and third adhesive portions 233, 243, and 253 are also be bent at the first, second, and third adhesive portions 233, 243, and 253 so as to be arranged in the Y-axis direction. The first, second, and third terminals 230, 240, and 250 may be prepared in a press type.

Accordingly, with regard to the power semiconductor module 200 according to the second embodiment of the present invention, the leads 233a, 243a, and 253a may be easily coupled onto the first, second, and third circuit patterns 221a, 221b, and 221c of the substrate 220 while the first, second, and third terminals 230, 240, and 250 are fixed to the module housing 210. In this case, as a coupling method, soldering, ultrasonic welding, etc. may be easily applied.

In addition, the leads 233a, 243a, and 253a may be arranged between the power devices 222 so as to uniformly distribute power to the right and left power devices 222, thereby effectively reducing stray inductance, and accordingly, current distribution between the first, second, and third circuit patterns 221a, 221b, and 221c as well as the power devices 222 may be balanced, thereby effectively preventing surge voltage from increasing.

A spring 212b is inserted and interposed between the first, second, and third terminals 230, 240, and 250 and the fixing portions 212 of the module housing 210. In addition, a washer 212c is interposed between the first, second, and third terminals 230, 240, and 250 and the bolts 212a.

Accordingly, press contact may be easily applied as a coupling method between the first, second, and third terminals 230, 240, and 250 and the substrate 220. That is, the spring 212b may support the first, second, and third terminals 230, 240, and 250 via elastic force to effectively prevent the substrate 220 from being damaged, which occurs during press contact.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A power semiconductor module:
a module housing comprising an accommodation space formed therein and fixing portions formed on an external surface thereof;
a printed circuit board included in the module housing, exposed through the accommodation space, and comprising circuit patterns (Cu patterns) on which power devices are arranged; and
a terminal fixedly coupled to the fixing portion, and comprising an input end for receiving power and leads adhered to a circuit pattern between the power devices and for distribution of supplied current.

2. The power semiconductor module as set forth in claim 1, wherein the fixing portion is formed with a groove with a concave shape so as to accommodate opposite ends of the terminal.

3. The power semiconductor module as set forth in claim 1, wherein the terminal is fixedly bolt-coupled to the fixing portion of the module housing.

4. The power semiconductor module as set forth in claim 1, wherein the terminal comprises:
a body portion comprising an input end;
a coupling portion protruding from the body portion and fixedly coupled to the fixing portion of the module housing; and
an adhesive portion protruding from the body portion and comprising a lead at an end thereof.

5. The power semiconductor module as set forth in claim 1, further comprising springs interposed between opposite ends of the terminal and the fixing portion of the module housing.

6. A power semiconductor module comprising:
a module housing comprising an accommodation space formed therein and fixing portions formed on an external surface thereof;
a printed circuit board included in the module housing, exposed through the accommodation space, and comprising a first circuit pattern on which power devices are arranged, a second circuit pattern that is electrically connected to the first circuit pattern and on which power devices are arranged, and a third circuit pattern that is electrically connected to the second circuit pattern;
a first terminal (P-terminal) with opposite ends fixedly coupled to the fixing portion, comprising an input end for receiving power and leads adhered between power devices of the first circuit pattern and for distributing supplied current;
a second terminal (Out-Terminal) with one end fixedly coupled to the fixing portion, comprising an output end for outputting current and leads adhered between power devices of the second circuit pattern and for distributing current; and
a third terminal (N-Terminal) with opposite ends fixedly coupled to the fixing portion, comprising leads coupled to the third circuit pattern.

7. The power semiconductor module as set forth in claim 6, wherein the fixing portion is formed with a groove with a concave shape.

8. The power semiconductor module as set forth in claim 6, wherein the first, second, and third terminals are fixedly bolt-coupled to the fixing portion of the module housing.

9. The power semiconductor module as set forth in claim 6, wherein the first terminal comprises:
a first body portion comprising an input end;
a first coupling portion protruding from opposite ends of the first body portion and fixedly coupled to the fixing portion of the module housing; and
a first adhesive portion protruding from the first body portion and comprising a lead at an end thereof.

10. The power semiconductor module as set forth in claim 6, wherein the second terminal comprises:
a second body portion comprising an output end;
a second coupling portion protruding from one end of the second body portion and fixedly coupled to the fixing portion of the module housing; and
a second adhesive portion protruding from the second body portion and comprising a lead at an end thereof.

11. The power semiconductor module as set forth in claim 6, wherein the third terminal comprises:
a third body portion;
a third coupling portion protruding from opposite ends of the third body portion and fixedly coupled to the fixing portion of the module housing; and
a third coupling portion protruding from the third body portion and comprising leads as at end thereof.

12. The power semiconductor module as set forth in claim 6, further comprising springs interposed between the first, second, and third terminals and the fixing portion of the module housing.
